(19) United States
(12) Patent Application Publication
(10) Pub. No.: US 2026/0118768 A1
(43) Pub. Date: Apr. 30, 2026

(54) LIQUID CIRCULATION UNIT AND SUBSTRATE PROCESSING APPARATUS INCLUDING SAME

(71) Applicant: SEMES CO., LTD., Cheonan-si (KR)

(72) Inventors: Hae Kyung KIM, Cheonan-si (KR); Tae Hoon LEE, Suwon-si (KR)

(73) Assignee: SEMES CO., LTD., Cheonan-si (KR)

(21) Appl. No.: 19/365,699

(22) Filed: Oct. 22, 2025

(30) Foreign Application Priority Data
Oct. 25, 2024 (KR) 10-2024-0147868

(51) Int. Cl. G03F 7/30; B01D 15/10; C02F 1/00; C02F 1/28; C02F 1/66; C02F 103/34; H10P 72/00

(52) U.S. Cl. CPC G03F 7/30; B01D 15/10; C02F 1/008; C02F 1/28; C02F 1/66; H10P 72/0448; C02F 2103/346; C02F 2209/06; C02F 2301/046

(57) ABSTRACT

Disclosed are a unit that circulates a liquid at a constant temperature and an apparatus for processing a substrate by maintaining a constant temperature of the treatment liquid by using the same. According to an embodiment, when a concentration measured by a sensor unit is equal to or greater than a set value, a controller controls a liquid circulation unit to discharge pure water to a discharge unit, supply pure water into a manifold, and add a rust inhibitor to prevent corrosion of the liquid circulation unit, and damage and leakage due to the corrosion, thereby improving the lifespan and reliability of a substrate processing apparatus.

### CROSS-REFERENCE TO RELATED APPLICATION

This application claims priority to and the benefit of Korean Patent Application No. 10-2024-0147868 filed in the Korean Intellectual Property Office on Oct. 25, 2024, the entire contents of which are incorporated herein by reference.

### TECHNICAL FIELD

The present invention relates to a liquid circulation unit and a substrate processing apparatus including the same, and more specifically, to a unit for circulating a liquid at a constant temperature and an apparatus for processing a substrate by maintaining a constant temperature of a treatment liquid.

### BACKGROUND ART

In order to manufacture a semiconductor device or a flat panel display, various processes, such as a deposition process, a photograph process, an etching process, and a cleaning process, are performed. Some of these processes include a processing method of processing a substrate by supplying a treatment liquid onto the substrate. According to an example, various processes include a cleaning process of cleaning a substrate with a cleaning liquid, an application process of applying a photoresist, and a developing process of forming a pattern by removing a film after an exposure treatment.

Maintaining a constant temperature of the treatment liquid when a substrate is treated with a treatment liquid is a very important factor in a semiconductor manufacturing process. In order to ensure a uniform chemical reaction on the substrate surface, the temperature of the treatment liquid must be constant, and fine fluctuations in temperature may greatly affect the treatment result. For example, when the temperature of the treatment liquid is out of a target range, the chemical reaction rate of the substrate surface changes, which may lead to non-uniform results in processes, such as formation of fine patterns or removal of impurities. These fluctuations not only lead to quality degradation of a product, but are also a major cause of decrease in the overall efficiency of the production line.

For this reason, various technical measures have been devised to maintain a constant temperature of the treatment liquid. Among them, the method of installing a separate line for allowing a heat transfer medium to flow while being adjacent to a line supplying the treatment liquid may stably maintain the temperature of a treatment liquid line by utilizing the thermal conductivity of the heat transfer medium, and may increase the stability of the entire process.

However, in an environment where the heat transfer medium flows for a long time, minute corrosion proceeds inside the line, which not only degrades the performance of the apparatus over time but can also lead to serious problems, such as contamination or leakage, of the treatment liquid. This corrosion problem makes it difficult to keep the temperature of the treatment liquid constant and may be a major cause of degrading the reliability and shortening lifespan of the apparatus.

### SUMMARY OF THE INVENTION

The present invention has been made in an effort to provide a liquid circulation unit capable of preventing corrosion in a component, in which a liquid flows, and damage and leakage due to the corrosion, and a substrate processing apparatus including the same.

The present invention has also been made in an effort to provide a liquid circulation unit capable of maintaining reliability in process processing by providing a constant temperature of a treatment liquid for processing a substrate, and a substrate processing apparatus including the same.

The present invention has also been made in an effort to provide a liquid circulation unit capable of improving the reliability and lifespan of an apparatus, and a substrate processing apparatus including the same.

The objectives of the present disclosure are not limited thereto and other objectives not stated herein may be clearly understood by those skilled in the art from the following description.

An exemplary embodiment of the present disclosure, an apparatus for processing a substrate, the apparatus comprising: a chamber for providing a treatment space for processing a substrate; a treatment liquid supply unit for supplying a treatment liquid to the treatment space; and a controller, wherein the treatment liquid supply unit includes: a treatment liquid supply source for storing the treatment liquid; a nozzle for discharging the treatment liquid to the substrate; a treatment liquid supply line for connecting the treatment liquid supply source and the nozzle; and a liquid circulation unit that is provided to circulate a liquid adjacent to the liquid supply line to maintain a constant temperature of the liquid, the liquid supply unit includes: a liquid supply unit for storing and supplying the liquid; a manifold to which the liquid is supplied from the liquid supply unit; an additive supply unit for putting an additive to the manifold; a circulation line provided to circulate a liquid supplied from the manifold to the liquid supply unit; and a sensor unit for measuring a concentration of foreign substances in the liquid, the circulation line is installed adjacent to the treatment liquid supply line, and when a measurement value of the sensor unit is equal to or greater than a set value, the controller may controls the liquid circulation unit to put the additive into the manifold.

According to the exemplary embodiment of the present invention, wherein the manifold includes a discharge line for discharging the liquid, and the controller may controls the liquid circulation unit to discharge the liquid through the discharge line when the measurement value of the sensor unit is equal to or greater than the set value.

According to the exemplary embodiment of the present invention, wherein the foreign substance is ion, and the additive may lowers a concentration of the ions.

According to the exemplary embodiment of the present invention, wherein the foreign substance is ion, and the additive may adsorbs the ion in the liquid.

According to the exemplary embodiment of the present invention, wherein the liquid supply unit includes: a liquid supply source for storing the liquid; and a liquid supply line for connecting the manifold and the liquid, the liquid supply line, the circulation line, and the manifold are made of a material containing metal, and the controller may puts the additive to prevent ions from dissolving in the liquid supply line, the circulation line, and the manifold, from the circulation line.

According to the exemplary embodiment of the present invention, wherein the liquid supply unit includes: a liquid supply source for storing the liquid; and a liquid supply line for connecting the manifold and the liquid, the controller may puts the additive to form a film inside the liquid supply line, the manifold, and the circulation line.

According to the exemplary embodiment of the present invention, wherein the sensor unit is provided to measure pH of the liquid, and the additive may increases the pH of the liquid.

According to the exemplary embodiment of the present invention, wherein the treatment liquid may be a developer.

According to the exemplary embodiment of the present invention, wherein the liquid may be pure water.

According to the exemplary embodiment of the present invention, wherein the liquid supply unit includes: a plurality of liquid supply sources for storing the liquid; a plurality of liquid supply lines for connecting the plurality of liquid supply sources and the manifold; and a valve installed in each of the plurality of liquid supply lines, and when a measured concentration of the liquid supplied from any one of the plurality of liquid supply sources is equal to or greater than a set value, the controller controls the liquid circulation unit to discharge the liquid through the discharge line and supply the liquid from another liquid supply source among the plurality of liquid supply sources.

An exemplary embodiment of the present disclosure, a unit for circulating a liquid, the unit comprising: a liquid supply unit for storing and supplying a liquid; a manifold to which the liquid is supplied from the liquid supply unit; an additive supply unit for putting an additive to the manifold; a circulation line provided to circulate the liquid supplied from the manifold to the liquid supply unit; a sensor unit for measuring a concentration of foreign substances in the liquid; and a controller, wherein when a measurement value of the sensor unit is equal to or greater than a set value, the controller may controls the additive supply unit to put the additive into the manifold.

According to the exemplary embodiment of the present invention, wherein the manifold includes a liquid discharge unit for discharging the liquid, and when the measurement value of the sensor unit is equal to or greater than the set value, the controller may controls the liquid discharge unit to discharge the liquid through the liquid discharge unit.

According to the exemplary embodiment of the present invention, wherein the liquid supply unit includes: a liquid supply source for storing the liquid; and a liquid supply line for connecting the manifold and the liquid, the liquid supply line, the circulation line, and the manifold are made of a material containing metal, and the controller may puts the additive to prevent ions from dissolving in the liquid supply line, the circulation line, and the manifold, from the circulation line.

According to the exemplary embodiment of the present invention, wherein the liquid supply source is provided in plural, the liquid supply line is provided to connect the plurality of liquid supply sources and the manifold, the liquid supply line includes a valve corresponding to each of the liquid supply sources, and when a measured concentration of the liquid supplied from any one of the plurality of liquid supply sources is equal to or greater than a set value, the controller may controls the liquid circulation unit to discharge the liquid through the discharge line and supply the liquid from another liquid supply source among the plurality of liquid supply sources.

According to the exemplary embodiment of the present invention, wherein the controller may puts the additive to form a film inside the liquid supply line, the manifold, and the circulation line.

According to the exemplary embodiment of the present invention, wherein the sensor unit is provided to measure pH of the liquid, and the additive may increases the pH of the liquid.

According to the exemplary embodiment of the present invention, wherein the liquid may be pure water.

An exemplary embodiment of the present disclosure, an apparatus for processing a substrate, the apparatus comprising: a chamber for providing a treatment space for processing a substrate; a treatment liquid supply unit for supplying a treatment liquid to the treatment space; and a controller, wherein the treatment liquid supply unit includes: a treatment liquid supply source for storing the treatment liquid; a nozzle for discharging the treatment liquid to the substrate; a treatment liquid supply line for connecting the treatment liquid supply source and the nozzle; and a liquid circulation unit that is provided to circulate the liquid adjacent to the treatment liquid supply line to maintain a constant temperature of the treatment liquid, the liquid circulation unit includes: a liquid supply unit for storing and supplying the liquid; a manifold to which the liquid is supplied from the liquid supply unit; an additive supply unit for putting an additive to the manifold; a circulation line provided to circulate the liquid supplied from the manifold to the liquid supply unit; a sensor unit for measuring a concentration of ions in the liquid; and a liquid discharge unit for discharging the liquid, and the circulation line is installed adjacent to the treatment liquid supply line, and the liquid is pure water, the additive is a rust inhibitor, the liquid supply line, the circulation line, and the manifold are made of a material containing metal, and when the concentration measured by the sensor unit is equal to or greater than a set value, the controller may controls the liquid circulation unit to discharge the pure water to the discharge unit, supply the pure water into the manifold, and add the rust inhibitor.

According to the exemplary embodiment of the present invention, wherein the rust inhibitor is mixed with the pure water to reduce the concentration of the ions in the pure water.

According to the exemplary embodiment of the present invention, wherein the treatment liquid may be a developer.

According to the exemplary embodiment of the present invention, it is possible to prevent corrosion in a component, in which a liquid flows, and damage and leakage due to the corrosion.

According to the exemplary embodiment of the present invention, it is possible to maintain reliability of process processing by providing a constant temperature of a treatment liquid for processing a substrate.

Further, according to the exemplary embodiment of the present invention, it is possible to improve the reliability and lifespan of an apparatus.

Effects of the present disclosure are not limited to those described above and effects not stated above will be clearly understood to those skilled in the art from the specification and the accompanying drawings.

### BRIEF DESCRIPTION OF THE DRAWINGS

The various features and advantages of the non-limiting exemplary embodiment of the present specification may become more apparent by reviewing the detailed description together with the accompanying drawings. The accompanying drawings are provided for illustrative purposes only and should not be construed as limiting the scope of claims. The accompanying drawings are not considered to be drawn to scale unless explicitly stated. For clarity, the various dimensions of the drawings may have been exaggerated.

FIG. 1 is a perspective view schematically illustrating a substrate processing apparatus according to an exemplary embodiment of the present invention.

FIG. 2 is a front view of the substrate processing apparatus of FIG. 1.

FIG. 3 is a top plan view of an applying block in the substrate processing apparatus of FIG. 1.

FIG. 4 is a top plan view of a developing block in the substrate processing apparatus of FIG. 1.

FIG. 5 is a top plan view schematically illustrating a transfer robot of FIG. 3.

FIG. 6 is a top plan view schematically illustrating an example of a heat treating chamber of FIG. 3 or FIG. 4.

FIG. 7 is a front view of the heat treating chamber of FIG. 6.

FIG. 8 is a cross-sectional view schematically illustrating an example of the heat treating chamber of FIG. 3 or FIG. 4.

FIG. 9 is a diagram schematically illustrating an exemplary embodiment of a liquid circulation unit of the present invention.

FIG. 10 is a diagram illustrating a state in which the liquid circulation unit of FIG. 9 is coupled to the liquid treating chamber of FIG. 8.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, a wafer is described as an example as an object to be processed. However, the technical idea of the present invention may be applied to devices used for processing other types of substrates other than wafers as objects to be processed.

Hereinafter, an exemplary embodiment of the present invention will be described with reference to the accompanying drawings.

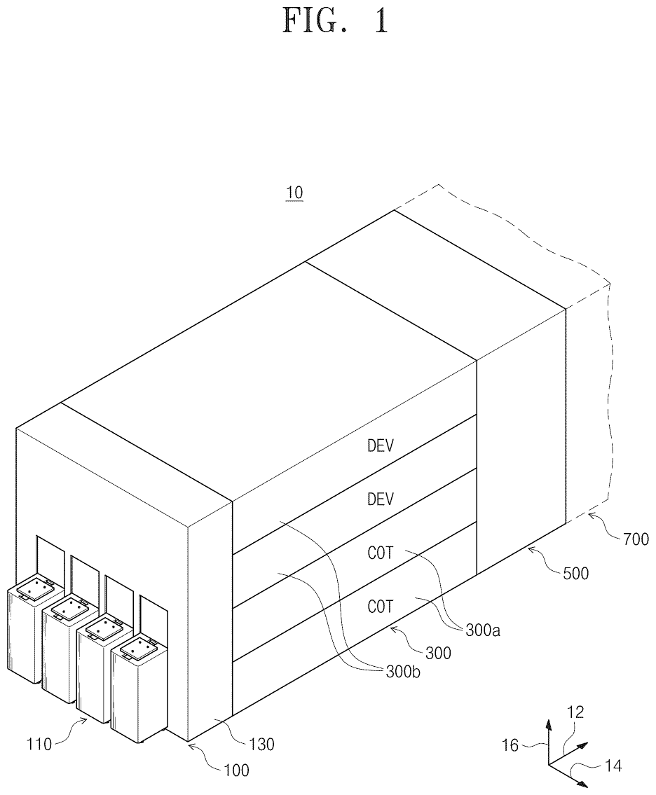

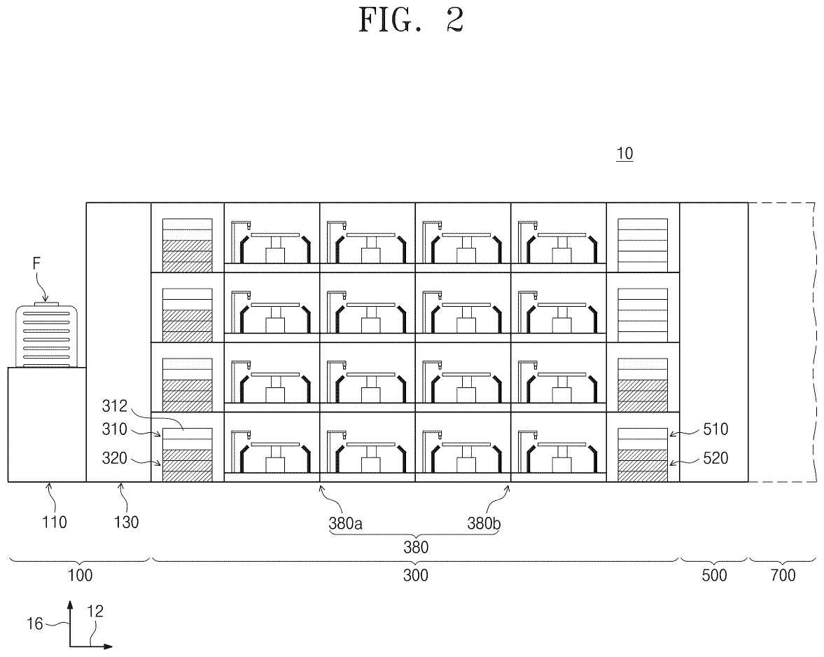

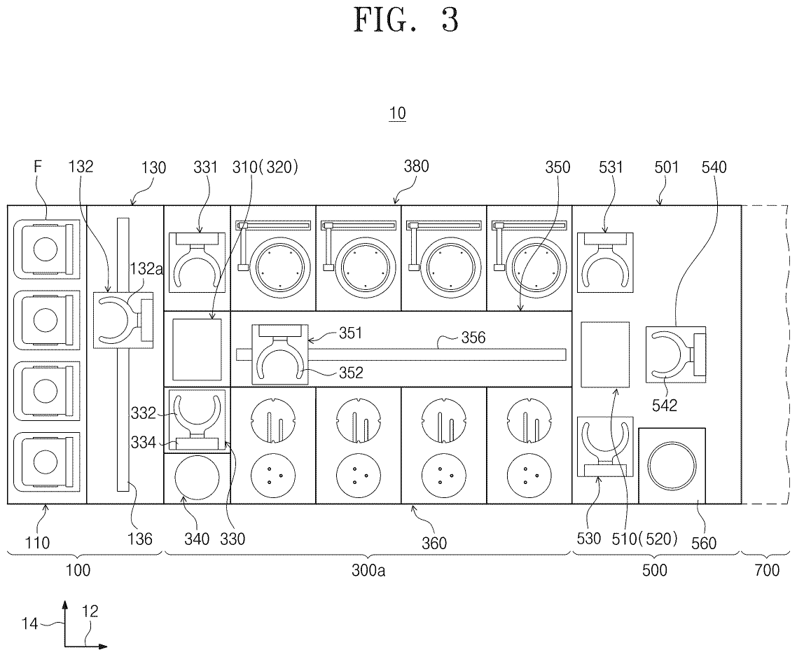

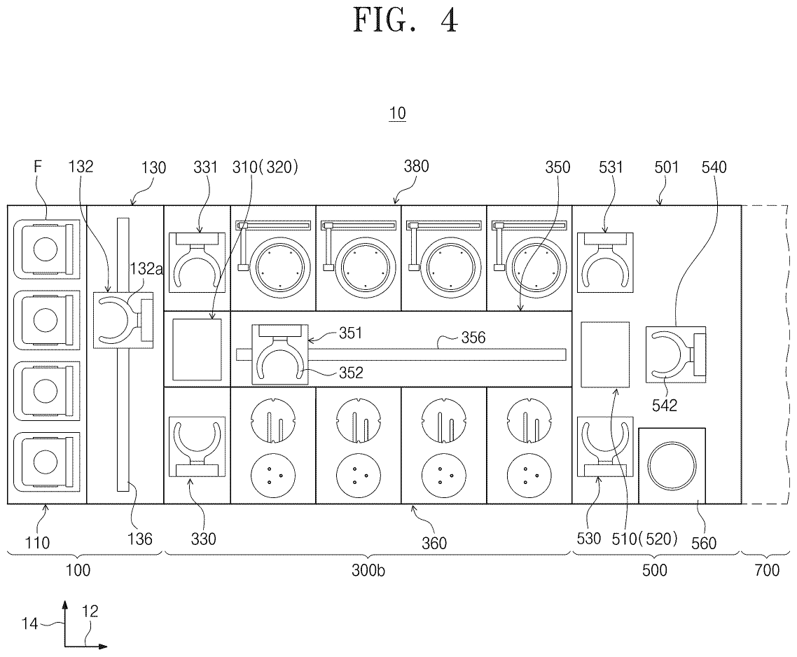

FIG. 1 is a perspective view schematically illustrating a substrate processing apparatus according to an exemplary embodiment of the present invention, and FIG. 2 is a front view of the substrate processing apparatus of FIG. 1. FIG. 3 is a top plan view of an applying block in the substrate processing apparatus of FIG. 1, and FIG. 4 is a top plan view of a developing block in the substrate processing apparatus of FIG. 1.

Referring to FIGS. 1 to 4, a substrate processing apparatus 10 includes an index module 100, a treating module 300, an interface module 500, and a controller 900. According to the exemplary embodiment, the index module 100, the treating module 300, and the interface module 500 are sequentially arranged in a line. Hereinafter, a direction in which the index module 100, the treating module 300, and the interface module 500 are disposed is referred to as a first direction 12, and when viewed from above, a direction perpendicular to the first direction 12 is referred to as a second direction 14, and a direction perpendicular to both the first direction 12 and the second direction 14 is referred to as a third direction 16.

The index module 100 is provided to transfer the substrate W between a container F in which the substrate W is accommodated and the treating module 300. A longitudinal direction of the index module 100 is provided in the second direction 14. The index module 100 includes a load port 110 and an index frame 130. The containers F in which the substrates W are accommodated are placed on the load ports 110. Based on the index frame 130, the load port 110 is located at a side opposite to the treating module 300. The load ports 110 may be provided in plurality, and the plurality of load ports 110 may be disposed in the second direction 14.

According to an example, as the container F, an airtight container F, such as a Front Open Unified Pod (FOUP), may be used. The container F may be placed on the load port 110 by a transfer means (not illustrated), such as an overhead transfer, an overhead conveyor, or an automatic guided vehicle, or an operator.

An index robot 132 is provided to the inside of the index frame 130. A guide rail 136 is provided to the inside of the index frame 130. A longitudinal direction of the guide rail 136 is provided in the second direction 14. The index robot 132 is mounted on the guide rail 136 to be movable along the guide rail 136. The index robot 132 includes a hand 132a on which the substrate W is placed. The hand 132a may be provided to be capable of forward and backward movement, linear movement in the third direction, and rotational movement in the third direction 16.

The treating module 300 may perform an application process and a development process on the substrate W. The treating module 300 includes an applying block 300a and a developing block 300b.

The applying block 300a performs an application process on the substrate W before the exposure process is performed. The developing block 300b performs a development process on the substrate W after the exposure process is performed. A plurality of applying blocks 300a is provided. A plurality of applying blocks 300a may be provided to be stacked on each other. A plurality of developing blocks 300b may be provided. A plurality of developing blocks 300b may be provided to be stacked on each other. According to an example, two applying blocks 300a are provided, and two developing blocks 300b are provided. A plurality of applying blocks 300a may be positioned under the developing block 300b.

According to an example, the plurality of applying blocks 300a may be provided in the same structure. The films applied to the substrate W in each of the plurality of applying blocks 300a may be the same type of film. The films applied to the substrate W selectively depending on the applying block 300a may be different types of films. The film applied to the substrate W includes a photo-resist film. The film applied to the substrate W may further include an anti-reflection film. The film applied to the substrate W selectively may further include a protective film.

Furthermore, the two developing blocks 300b may be provided in the same structure. The developer supplied to the substrate W by the plurality of developing blocks 300b may be the same type of liquid. Optionally, the developer supplied to the substrate W according to the developing block 300b may be different types of developer. For example, a process of removing a light-irradiated region from among regions of a register film on the substrate W may be performed in any one of the two developing blocks 300b, and a process of removing a region not irradiated with light may be performed by the other one of the two developing blocks 300b. A detailed configuration and structure of the applying block 300a and the developing block 300b will be described later.

The interface module 500 connects the treating module 300 to an external exposure device 700. The interface module 500 includes an interface frame 501, a buffer unit 510, a cooling unit 520, a transfer mechanism 530, an interface robot 540, and an additional process chamber 560.

A fan filter unit may be provided at an upper end of the interface frame 501 to form a descending airflow therein. The buffer unit 510, the cooling unit 520, the transfer mechanism 530, the interface robot 540, and the additional process chamber 560 are disposed within the interface frame 501.

Structures and arrangements of the buffer unit 510 and the cooling unit 520 may be provided to be the same as or similar to those of the buffer unit 310 and the cooling unit 320 provided in the treating module 300. The buffer unit 510 and the cooling unit 520 are disposed adjacent to an end portion of the transfer chamber 350. The substrate W transferred between the treating module 300, the cooling unit 520, the additional process chamber 560, and the exposure device 700 may stay temporarily in the buffer unit 510. The cooling unit 520 may be provided only at a height corresponding to the applying block 300a between the applying block 300a and the developing block 300b.

The transfer mechanism 530 may transfer the substrate W between the buffer units 510. In addition, the transfer mechanism 530 may transfer the substrate W between the buffer unit 510 and the cooling unit 520. The transfer mechanism 530 may be provided in the same or similar structure as or to the transfer mechanism 330 of the treating module 300. Another transfer mechanism 531 may be further provided in an area opposite to the region in which the transfer mechanism 530 is provided with respect to the buffer unit 510.

The interface robot 540 is disposed between the buffer unit 510 and the exposure device 700. The interface unit 540 is provided to transfer the substrate W between the buffer unit 510, the cooling unit 520, the additional process chamber 560, and the exposure apparatus 700. The interface robot 540 has a hand 542 on which the substrate W is placed, and the hand 542 may be provided to move forward and backward, rotate based on an axis parallel to the third direction 16, and be movable along the third direction 16.

The additional process chamber 560 may perform a predetermined additional process before the substrate W on which the process has been completed in the applying block 300a is loaded into the exposure device 700. Optionally, the additional process chamber 560 may perform a predetermined additional process before the substrate W on which the process has been completed in the exposure device 700 is loaded into the developing block 300b. According to an example, the additional process may be an edge exposure process for exposing an edge region of the substrate W, an upper surface cleaning process for cleaning the upper surface of the substrate W, a lower surface cleaning process for cleaning the lower surface of the substrate W, or an inspection process of performing a predetermined inspection on the substrate W. A plurality of additional process chambers 560 may be provided, and they may be provided to be stacked on each other.

Referring back to FIG. 3, the applying block 300a includes a buffer unit 310, a cooling unit 320, a hydrophobization chamber 340, a transfer chamber 350, a heat treating chamber 360, and a liquid treating chamber 380.

The buffer unit 310, the cooling unit 320, and the hydrophobization chamber 340 are disposed adjacent to the index block 100. The hydrophobization chamber 340 and the buffer unit 310 may be sequentially disposed along the second direction 14. Also, the cooling unit 320 and the buffer unit 310 may be stacked in a vertical direction.

The buffer unit 310 includes one or a plurality of buffers 312. When a plurality of buffers 312 is provided, a plurality of buffers 312 may be disposed to be stacked therebetween. The buffer 312 provides a space in which the substrate W stays when the substrate W is transferred between the index module 100 and the treating module 300. The hydrophobization chamber 340 hydrophobizes the surface of the substrate W. The hydrophobization treatment may be performed before performing the application process on the substrate W. The hydrophobization treatment may be performed by supplying the hydrophobization gas to the substrate W while heating the substrate W. The cooling unit 320 cools the substrate W. The cooling unit 320 includes one or a plurality of cooling plates. When a plurality of cooling plates is provided, a plurality of cooling plates may be disposed to be stacked on each other. According to an example, the cooling unit 320 may be disposed below the buffer unit 310. A flow path through which cooling water flows may be formed in the cooling plate. The substrate W on which the hydrophobization treatment has been completed may be cooled in the cooling plate.

The transfer mechanism 330 is provided between the hydrophobization chamber 340 and the buffer unit 310 and between the hydrophobization chamber 340 and the cooling unit 320. The transfer mechanism 330 is provided to be able to transfer the substrate W between the buffer unit 310, the hydrophobic chamber 340, and the cooling unit 320.

The transfer mechanism 330 has a hand 332 on which the substrate W is placed, and the hand 332 may be provided to move forward and backward, rotate around the third direction 16, and be movable along the third direction 16. According to an example, the transfer mechanism 330 is moved in the third direction 16 along the guide rail 334. The guide rail 334 extends from the applying block located at the bottommost end among the applying blocks 300a to the developing block located at the topmost end among the developing blocks 300b. Accordingly, the transfer mechanism 330 may transfer the substrate W between the blocks 300a and 300b provided on different layers. For example, the transfer mechanism 330 may transfer the substrate W between the applying blocks 300a positioned on different layers. In addition, the transfer mechanism 330 may transfer the substrate W between the applying block 300a and the development block 300b.

Furthermore, another transfer unit 331 may be additionally provided at an opposite side to the side to which the hydrophobization chamber 340 is provided with respect to the buffer unit 310. The other transfer unit 331 may be provided to transfer the substrate W between the buffer unit 310 and the cooling unit 320 provided in the same blocks 300a and 300b. Furthermore, the other transfer unit 331 may be provided to transfer the substrate W between the buffer unit 310 and the cooling unit 320 provided in different blocks 300a and 300b.

The transfer chamber 350 may be provided so that a longitudinal direction is parallel to the first direction 12. One end of the transfer chamber 350 may be located adjacent to the buffer unit 310 and/or the cooling unit 320. The other end of the transfer chamber 350 may be located adjacent to the interface module 500.

A plurality of heat treating chambers 360 is provided. Some of the heat treating chambers 360 are disposed along the first direction 12. Also, some of the heat treating chambers 360 may be stacked along the third direction 16. All of the heat treating chambers 360 may be located on one side of the transfer chamber 350.

The liquid treating chamber 380 performs a liquid film forming process of forming a liquid film on the substrate W. According to an example, the liquid film forming process includes a resist film forming process. The liquid film forming process may include an antireflection film forming process. Optionally, the liquid film forming process may further include a protective film forming process. A plurality of liquid treating chambers 380 is provided. The liquid treating chambers 380 may be located on the side opposite to the heat treating chamber 360. For example, all liquid treating chambers 380 may be located on the other side of the transfer chamber 350. The liquid treating chambers 380 are arranged side by side along the first direction 12. Optionally, some of the liquid treating chambers 360 may be stacked along the third direction 16.

According to an example, the liquid treating chambers 380 include a front end liquid treating chamber 380a and a rear end liquid treating chamber 380b. The front end liquid treating chamber 380a is disposed relatively adjacent to the index module 100, and the rear end liquid treating chamber 380b is disposed more adjacent to the interface module 500.

The front end liquid treating chamber 380a applies a first liquid on the substrate W, and the rear end liquid treating chamber 380b applies a second liquid on the substrate W. The first liquid and the second liquid may be different types of liquids. According to an example, the first liquid may be a liquid for forming the antireflection film, and the second liquid may be a liquid for forming the photoresist film. The photoresist film may be formed on the substrate W to which the antireflection film is applied. Optionally, the first liquid may be a liquid for forming the photoresist film, and the second liquid may be a liquid for forming the antireflection film. In this case, the antireflection film may be formed on the substrate W on which the photoresist film is formed. Optionally, the first liquid and the second liquid may be the same type of liquid, and all of these may be liquids for forming a photoresist film.

Referring to FIG. 4, the developing block 300b includes the buffer unit 310, the cooling unit 320, the transfer chamber 350, the heat treating chamber 360, and the liquid treating chamber 380. The arrangement of the buffer unit 310, the cooling unit 320, the transfer chamber 350, the heat treating chamber 360, and the liquid treating chamber 380 in the developing block 300b may be the same as the arrangement of the buffer unit 310, the cooling unit 320, the transfer chamber 350, the heat treating chamber 360, and the liquid treating chamber 380 in the applying block 300a. When viewed from above, the buffer unit 310, the cooling unit 320, the transfer chamber 350, the heat treating chamber 360, and the liquid treating chamber 380 in the developing block 300b, and the buffer unit 310, the cooling unit 320, the transfer chamber 350, the heat treating chamber 360, and the liquid treating chamber 380 in the applying block 300a may be disposed at positions overlapping each other.

The heat treating chamber 360 performs a heating process on the substrate W. The heating process includes a post-exposure baking process performed on the substrate W on which the exposure process has been completed and a hard baking process performed on the substrate W on which the development process has been completed.

The liquid treating chamber 380 performs a developing process of supplying a developer onto the substrate W and developing the substrate W. The exposed portion or an unexposed portion of the photoresist dissolves by the developer. Accordingly, a pattern may be formed on the substrate W.

In FIG. 3 or 4, a transfer robot 351 is provided in the transfer chamber 350. The transfer robot 351 transfers the substrate W between the buffer unit 310, the cooling unit 320, the heat treating chamber 360, the liquid treating chamber 380, and the buffer unit 510 or the cooling unit 520 of the interface module 500. According to an example, the transfer robot 351 has a hand 352 on which the substrate W is placed. The hand 352 may be provided to move forward and backward, rotate around the third direction 16, and be movable along the third direction 16. A guide rail 356 whose length direction is provided parallel to the first direction 12 is provided in the transfer chamber 350, and the transfer robot 351 may be provided movable on the guide rail 356.

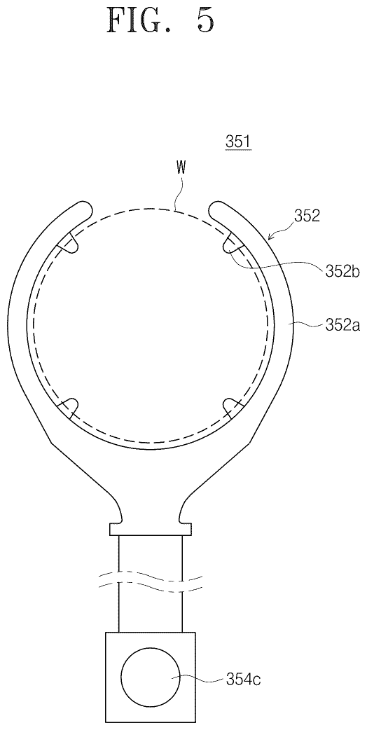

FIG. 5 is a diagram illustrating an example of the hand of the transfer robot. Referring to FIG. 5, the hand 352 has a base 352a and a support protrusion 352b. The base 352a may have an annular ring shape in which a portion of the circumference is bent. The base 352a has an inner diameter larger than the diameter of the substrate W. The support protrusion 352b extends inward from the base 352a. A plurality of support protrusions 352b is provided and supports an edge region of the substrate W. According to an example, four support protrusions 352b may be provided at equal intervals.

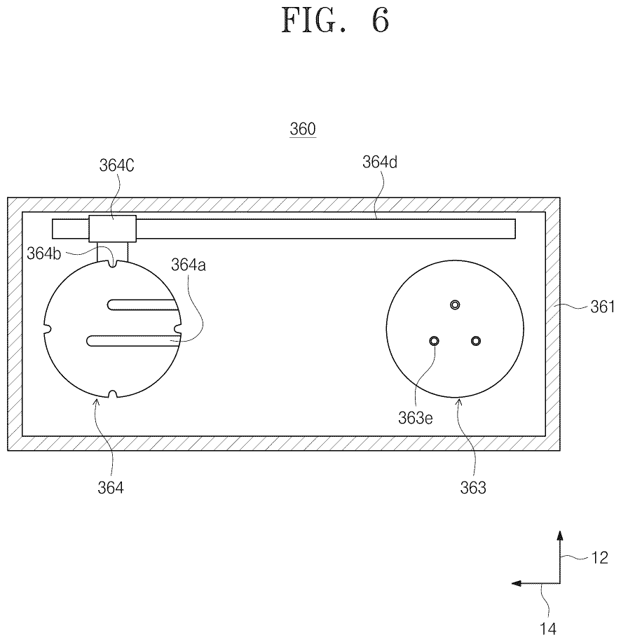

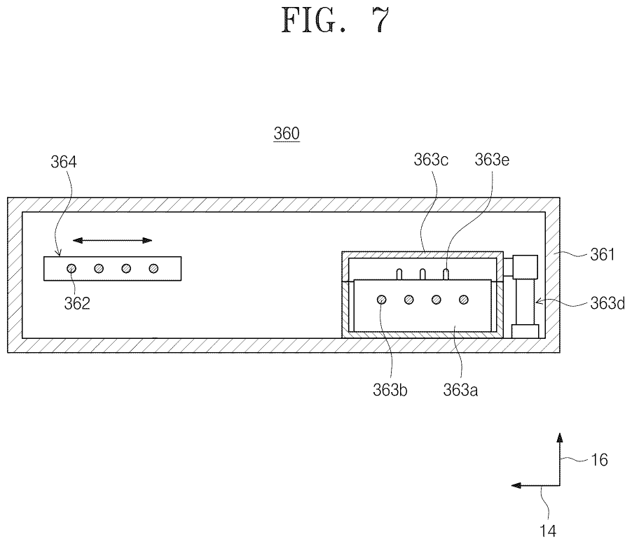

FIG. 6 is a top plan view schematically illustrating an example of the heat treating chamber of FIG. 3 or FIG. 4, and FIG. 7 is a front view of the heat treating chamber of FIG. 6.

Referring to FIGS. 6 and 7, the heat treating chamber 360 includes a housing 361, a heating unit 363, and a transfer plate 364.

The housing 361 is provided in a generally rectangular parallelepiped shape. An entrance opening (not illustrated) through which the substrate W enters and exits is formed on a sidewall of the housing 361. The entrance opening may remain open. A door (not illustrated) may be provided to selectively open and close the entrance opening. The heating unit 363 and the transfer plate 364 are provided within the housing 361.

The heating unit 363 includes a heating plate 363a, a cover 363c, and a heater 363b. When viewed from above, the heating plate 363a has a generally circular shape. The heating plate 363a has a larger diameter than the substrate W. The heater 363b is installed on the heating plate 363a. The heater 363b may be provided as a heating wire or a heating pattern that generates heat by supplying power. A lift pin 363e is provided at the heating plate 363a. The lift pin 363e is provided to be movable in the vertical direction along the third direction 16. The lift pin 363e receives the substrate W from the transfer robot 352 and puts the substrate W down on the heating plate 363a or lifts the substrate W from the heating plate 363a to hand over the substrate to the transfer robot 352. According to an example, three lift pins 363e may be provided. The cover 363c has an inner space with an open lower portion. The cover 363c is located above the heating plate 363a and is vertically moved by a driver 363d. A space formed by the cover 363c and the heating plate 363a by moving the cover 363c is provided as a heating space for heating the substrate W.

The transfer plate 364 is generally provided with a disk shape and has a diameter corresponding to that of the substrate W. A notch 364b is formed at an edge of the transfer plate 364. The notch 364b may have a shape corresponding to that of the protrusion 352b formed in the hand of the transfer robot 352 described above. Also, the notches 364b are provided by the number corresponding to that of the protrusions 352b formed in the hand, and are formed at positions corresponding to the protrusions 352b. When the upper and lower positions of the hand and the transfer plate 364 are changed at the position where the hand and the transfer plate 364 are aligned in the vertical direction, the substrate W is transferred between the hand 354 and the transfer plate 364. The transfer plate 364 is mounted on the guide rail 364d and may be moved along the guide rail 364d by the driver 364c.

A plurality of slit-shaped guide grooves 364a is provided in the transfer plate 364. The guide groove 364a extends from the end of the transfer plate 364 to the inside of the transfer plate 364. The guide groove 364a is provided so that a longitudinal direction thereof is the second direction 14, and the guide grooves 364a are spaced apart from each other along the first direction 12. The guide groove 364a prevents the transfer plate 364 and the lift pin 363e from interfering with each other when the substrate W is taken over between the transfer plate 364 and the heating unit 363.

The transfer plate 364 is made of a material having high thermal conductivity. According to an example, the transfer plate 364 may be made of a metal material.

A cooling flow path 364 is formed in the transfer plate 364. The cooling water is supplied to the cooling flow path 364. The substrate W on which the heating has been completed in the heating unit 363 may be cooled in the middle of being transferred by the transfer plate 364. In addition, while the transfer plate 364 is stopped for the hand-over of the substrate W by the transfer robot 351, the substrate W may be cooled on the transfer plate 364.

Optionally, a cooling unit may be additionally provided in the housing 361. In this case, the cooling unit may be disposed in parallel with the heating unit 363. The cooling unit may be provided as a cooling plate having a passage through which cooling water flows. The substrate on which heating in the heating unit has been completed may be transferred to the cooling unit to be cooled.

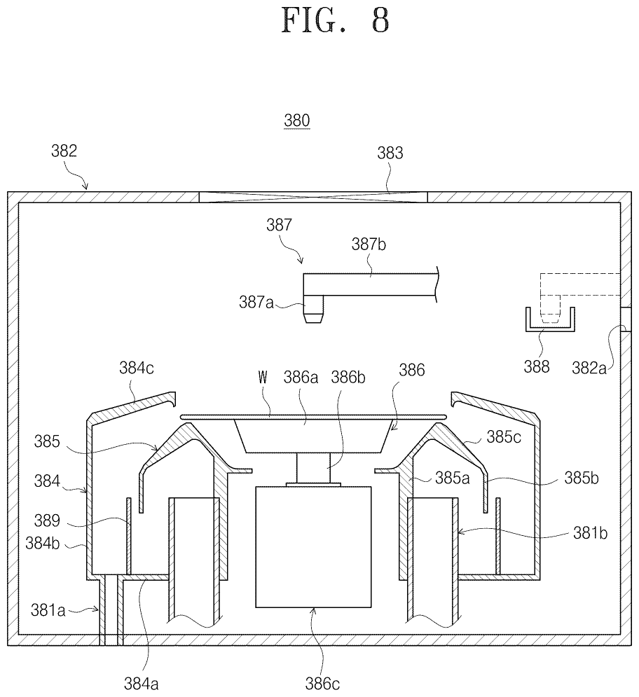

FIG. 8 is a cross-sectional view schematically illustrating the heat treating chamber of FIG. 3 or FIG. 4.

Referring to FIG. 8, the liquid treating chamber 380 has a housing 382, an outer cup 384, a support unit 386, a treatment liquid supply unit 387, and a liquid circulation unit 1000.

The housing 382 is provided in a rectangular cylindrical shape having an inner space. An opening 382a is formed in one side of the housing 382. The opening 382a functions as a passage through which the substrate W enters and exits. A door (not illustrated) is installed in the opening 382a, and the door opens and closes the opening. A fan filter unit 383 for supplying descending airflow to the inner space is disposed on the upper wall of the housing 382. The fan filter unit 383 includes a fan for introducing external air into the inner space and a filter for filtering external air. The outer cup 384 is provided in the inner space of the housing 382. The outer cup 384 has a treatment space with an open top.

The outer cup 384 has a bottom wall 384a, a side wall 384b, and an upper wall 384c. The inside of the outer cup 384 is provided as the inner space described above. The inner space includes an upper treatment space and a lower exhaust space.

The bottom wall 384a is provided in a circular shape and has an opening in the center thereof. The side wall 384b extends upward from the outer end of the bottom wall 384a. The side wall 384b is provided in a ring shape and is provided perpendicular to the bottom wall 384a. For example, the side wall 384b extends to the same height as the upper surface of the support plate 386a or to a height slightly lower than the upper surface of the support plate 386a. The upper wall 384c has a ring shape and an opening in the center thereof. The upper wall 384c is provided to be inclined upward from the upper end of the side wall 384b toward the central axis of the outer cup 384.

The outer cup 384 may also be provided with a gas-liquid separator 389. The gas-liquid separator 389 may extend upward from the bottom wall 384a of the outer cup 384. The gas-liquid separator 389 may be provided in a ring shape. When viewed from above, the gas-liquid separator 389 may be positioned between the sidewall 384b of the outer cup 384 and the outer wall 385b of the guide cup 385. The upper end of the gas-liquid separator 389 may be positioned lower than the lower end of the outer wall 385b of the guide cup 385.

A discharge pipe 381a and an exhaust pipe 381b for discharging a treatment liquid are connected to the bottom wall 384a of the outer cup 384. The discharge pipe 381a may be connected to the outer cup 384 from the outside of the gas-liquid separator 389. The exhaust pipe 381b may be connected to the outer cup 384 from the inside of the gas-liquid separator 389.

The guide cup 385 is located inside the outer cup 384. The guide cup 385 has an inner wall 385a, an outer wall 385b, and an upper wall 385c. The inner wall 385a has a through hole penetrating in the vertical direction. The inner wall 385a is disposed to surround a driver 386c. The inner wall 385a minimizes the exposure of the driver 386c to the airflow 84 in the treatment space. The rotation shaft 386b or/and the driver 386c of the support unit 386 extend in the vertical direction through the through hole. The outer wall 385b is disposed to be spaced apart from the inner wall 385a and to surround the inner wall 385a. The outer wall 385b is positioned to be spaced apart from the side wall 384b of the outer cup 384. The inner wall 385a is disposed to be spaced apart upward from the bottom wall 384a of the outer cup 384. The upper wall 385c connects the upper end of the outer wall 385b and the upper end of the inner wall 385a. The upper wall 385c has a ring shape and is disposed to surround the support plate 386a. According to an example, the upper wall 385c has a shape convex upward.

The support unit 386 supports the substrate W in the treatment space of the outer cup 384. The support unit 386 includes a support plate 386a, a rotating shaft 386b, and a driver 386c. The support plate 386a has a circular upper surface. The support plate 386a has a smaller diameter than the substrate W. The support plate 386a is provided to support the substrate W by vacuum pressure. The rotating shaft 386b is coupled to the center of the bottom surface of the support plate 386a, and the rotating shaft 386b is provided with the driver 386c configured to provide the rotating shaft 386b with rotating force. The driver 386c may be a motor. Also, a lifting driver (not illustrated) for adjusting a relative height of the support plate 386a and the outer cup 384 may be provided.

Among the treatment spaces, a space below the support plate 386a may be provided as an exhaust space. According to an example, the exhaust space may be defined by the guide cup 385. A space surrounded by or below the outer wall 385b, the upper wall 385c, and the inner wall 385a of the guide cup 385 may be provided as an exhaust space.

The treatment liquid supply unit 387 supplies a treatment liquid onto the substrate W. When the liquid treating chamber 380 is provided to the applying block 300a, the treatment liquid may be a liquid for forming a photoresist film, an antireflection film, or a protective film. When the liquid treating chamber 380 is provided to the developing block 300b, the treatment liquid may be a developer. Hereinafter, the present invention will be described that the liquid treating chamber 380 is provided to the developing block 300b as an example.

The treatment liquid supply unit 387 has a nozzle 387a, a nozzle support 387b, a treatment liquid supply source (not illustrated), and a treatment liquid supply line 387c. The treatment liquid supply source stores a treatment liquid to be supplied. The treatment liquid supply line 387c connects the treatment liquid supply source and the nozzle 387a. The nozzle 387a discharges the treatment liquid to the substrate W. The nozzle 387a is supported by the nozzle support 387b. The nozzle support 387b moves the nozzle 387a between a process position and a standby position. In the process position, the nozzle 387a supplies the treatment liquid to the substrate W placed on the support plate 386a, and the nozzle 387a, which has completed supplying the treatment liquid, waits in the standby position. In the standby position, the nozzle 387a stands by at the home port 388, and the home port 388 is located outside the outer cup 384 within the housing 382.

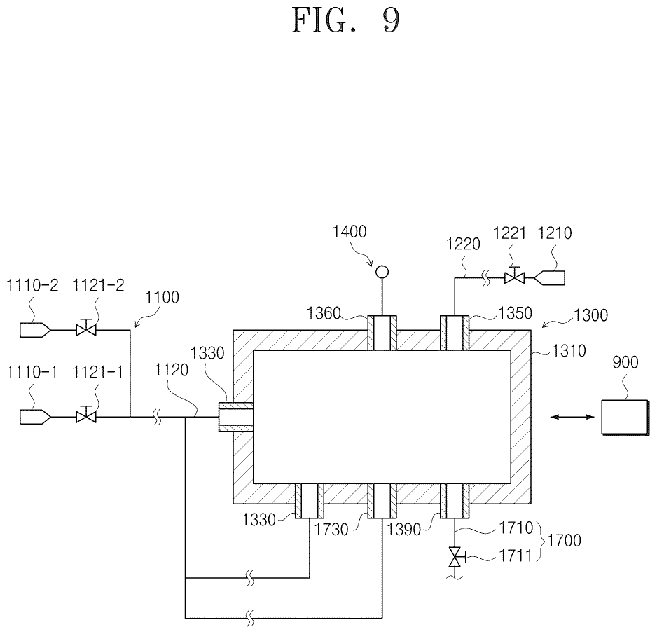

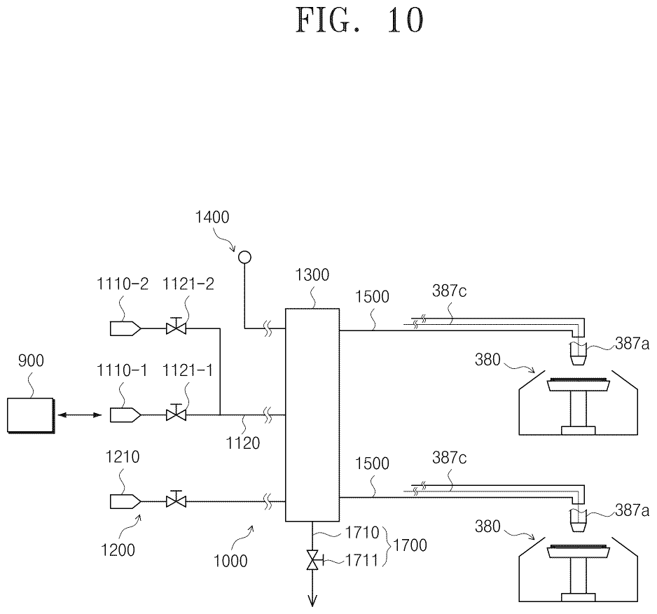

FIG. 9 is a diagram schematically illustrating an exemplary embodiment of the liquid circulation unit of the present invention, and FIG. 10 is a diagram illustrating a state in which the liquid circulation unit of FIG. 9 is coupled to the liquid treating chamber of FIG. 8. Referring to FIGS. 9 and 10, the liquid circulation unit 1000 may be configured to circulate a liquid. The liquid circulation unit 1000 may include a liquid supply unit 1100, an additive supply unit 1200, a manifold 1300, a sensor unit 1400, a circulation line 1500, and a liquid discharge unit 1700.

The liquid supply unit 1100 may store and supply a liquid. The liquid supply unit 1100 may include a liquid supply source 1110 and a liquid supply line 1120. The liquid supply source 1110 stores and supplies a liquid. According to an example, the liquid supply source 1110 may be provided in the form of a tank or a bottle, but the present invention is not limited thereto and any configuration having a structure for storing a liquid is sufficient. According to an example, the liquid may be pure water. Further, the liquid supply source 1110 may include a means (not illustrated) for supplying a liquid to the liquid supply line 1120. A valve 1121 and a pump, which are not illustrated, may be installed in the liquid supply line 1120 to supply a liquid from the liquid supply source 1110 to the liquid supply line 1120. Further, the liquid supply source 1110 or the liquid supply line 1120 may be further provided with a temperature adjusting member (not illustrated). The temperature adjusting member may be provided to control a temperature of the liquid and to maintain a temperature of the liquid to be constant. The temperature adjusting member may be installed on the liquid supply source 1110 and/or the liquid supply line 1120. The temperature adjusting member may include a heater increasing a temperature of the liquid, a cooler decreasing a temperature of the liquid, and the like. However, the present invention is not limited thereto, and it may be sufficient if the temperature of the liquid is controlled and maintained constant. Further, a plurality of liquid supply sources 1110 may be provided. A plurality of liquid supply sources 1110 may be provided to supply liquid to the manifold 1300 from any one of a plurality of liquid supply sources 1110. According to an example, a plurality of liquid supply sources 1110 are all connected to the liquid supply line 1120, valves 1121-1 and 1121-2 corresponding to the liquid supply sources are installed in the liquid supply line 1120, and the controller 900 may control the opening and closing of the valves 1121-1 and 1121-2 to supply the liquid from only one liquid supply source 1110-1.

The additive supply unit 1200 may store and supply the additive. The additive supply unit may include an additive supply source 1210 and an additive supply line 1220. The additive supply source 1210 stores and supplies the additive. According to an example, the additive supply source 1210 may be provided in the form of a tank or a bottle, but the present invention is not limited thereto and any configuration having a structure for storing the additive may be sufficient. Further, a plurality of additive supply sources 1210 may be provided. Each additive supply source 1210 may be provided to supply different additives. The additive supply source 1210 may include a means (not illustrated) for supplying the additive to the additive supply line 1220. A valve 1221, a pump, and the like may be installed in the additive supply line 1220 to supply the additive from the additive supply source 1210 to the additive supply line 1220. For example, the additive may be a rust inhibitor that prevents corrosion of the metal surface, and the rust inhibitor may be phosphate, chromates, nitrates, nitrites, organic rust inhibitors, amine-based inhibitors, silicates, and the like, but it is sufficient if the rust inhibitor is properly known to those skilled in the art.

Hereinafter, the principle that the rust inhibitor prevents corrosion of metal components when the liquid is provided with pure water will be described. The rust inhibitor forms a thin protective film on the metal surface so that the metal does not come into direct contact with pure water. The film may protect the metal from oxidation or corrosion. In addition, the rust inhibitor may suppress corrosion by adjusting the pH of the water. Pure water is easily acidified, and the rust inhibitor may keep the pure water neutral or weakly alkaline to prevent the metal from being less corroded. In addition, the rust inhibitor may suppress corrosion by preventing oxidation of metal by adsorbing or neutralizing an oxidizing agent, such as oxygen in water. In addition, elution of metal may be prevented by preventing dissolution or reaction of metal ions in pure water.

The manifold 1300 may be connected to the liquid supply source 1110 through the liquid supply line 1120. The manifold 1300 may include a body 1310, a first inlet end 1330, a second inlet end 1350, a supply end 1370, and a discharge end 1390. The body 1310 provides a space therein. The liquid introduced into the body 1310 and the additive may be mixed with each other. Further, the body 1310 is provided so that the first inlet end 1330, the second inlet end 1350, the supply end 1370, and the discharge end 1390 are installed. The first inlet end 1330 is a portion through which a liquid supplied from the liquid supply line 1110 is introduced. The second inlet end 1350 is a portion through which the additive supplied from the additive supply line 1210 are introduced. The supply end 1370 is a portion through which a liquid is supplied to the circulation line 1500 to be described later. Also, a plurality of supply ends 1370 may be provided. The discharge end 1390 is a portion through which a liquid is discharged. The liquid in the manifold 1300 may be discharged to the outside through the discharge end 1390. The first inlet end 1330, the second inlet end 1350, the supply end 1370, and the discharge end 1390 are provided to be coupled to the body 1310, and may be integrally provided. In addition, the first inlet end 1330, the second inlet end 1350, the supply end 1370, and the discharge end 1390 may be provided to have various arrangements, and those illustrated in FIGS. 9 and 10 are only examples. The first inlet end 1330, the second inlet end 1350, the supply end 1370, and the discharge end 1390 may be provided to be appropriately disposed for each purpose by a person skilled in the art.

The sensor unit 1400 may be installed on the manifold 1300. The sensor unit 1400 may be provided to be connected to a connection end 1360 provided on the body 1310. The connection end 1360 may be provided to be the same as or similar to the first inlet end 1330, the second inlet end 1350, the supply end 1370, and the discharge end 1390. The sensor unit 1400 may measure a concentration of a foreign substance in the liquid introduced into the manifold 1300. According to an exemplary embodiment, the foreign substance is ions, the sensor unit 1400 may include a Total Dissolved Solids (TDS) sensor, and the TDS sensor may measure a concentration of ions in a liquid. The controller 900 may determine whether to put a rust inhibitor and replace a liquid based on the measured concentration of ions in the liquid.

The circulation line 1500 provides a path through which a liquid circulates. The circulation line 1500 may be installed on the supply end 1370. The circulation line 1500 may be installed such that the liquid supplied from the supply end 1370 is introduced again through the first inlet end 1330. A plurality of circulation lines 1500 may be provided. The circulation line 1500 may be provided as a number corresponding to the number of supply ends 1370. The circulation line 1500 may be provided adjacent to the treatment liquid supply line 378d. The circulation line 1500 may be provided so that the liquid flowing through the circulation line 1500 is capable of maintaining a constant temperature of the treatment liquid flowing through the treatment liquid supply line 387c. According to an example, a material of the circulation line 1500 may be made of a Steel Use Stainless (SUS) material.

The liquid discharge unit 1700 discharges a liquid from the manifold 1300. The liquid discharge unit 1700 is provided to discharge the liquid in the manifold 1300 through the discharge line 1710. The discharge line 1700 may be coupled to the discharge end 1390. A valve 1711 is installed in the discharge line 1710, and the controller 900 may determine whether to discharge the liquid in the manifold 1300, and control the valve 1711 according to the determination.

The controller 900 may control the entire operation of the substrate treating apparatus 10. The controller 900 may include a process controller formed of a microprocessor (computer) that executes the control of the substrate treating apparatus 10, a user interface formed of a keyboard in which an operator performs a command input operation or the like in order to manage the substrate treating apparatus 10, a display for visualizing and displaying an operation situation of the substrate treating apparatus 10, and the like, and a storage unit storing a control program for executing the process executed in the substrate treating apparatus 10 under the control of the process controller or a program, that is, a treating recipe, for executing the process in each component according to various data and treating conditions. Further, the user interface and the storage unit may be connected to the process controller. The processing recipe may be stored in a storage medium in the storage unit, and the storage medium may be a hard disk, and may also be a portable disk, such as a CD-ROM or a DVD, or a semiconductor memory, such as a flash memory.

Hereinafter, a method of controlling the liquid supply unit 1000 by the controller 900 will be described by referring to reference numerals illustrated in FIGS. 1 to 10.

When the liquid is circulated along the liquid supply line 1110, the manifold 1300, and the circulation line 1500 for a long time, corrosion may occur in the above components 1100, 1300, and 1500 due to ions present in the liquid, temperature and pH of the liquid, and the like. When the liquid is provided as pure water, and the above components 1100, 1300, and 1500 include a metal, the liquid may promote corrosion of the metal surface. This is because pure water is easily acidified, may include an oxidizing agent such as oxygen, and may promote dissolution of metal ions.

The controller 900 determines whether to put the rust inhibitor and whether to replace the liquid according to the concentration measured by the sensor unit 1400. When the concentration measured by the sensor unit 1400 is higher than a set value, the liquid supply unit 1100 and the additive supply unit 1200 may be controlled to replace the liquid and put a rust inhibitor. The set value may be provided with an appropriate value for preventing the metal surface from corroding or metal ions from being eluted. When the controller 900 determines to replace the liquid and put the rust inhibitor, the controller 900 discharges the liquid through the discharge unit 1700, controls the valves 1121-1 and 1121-2 provided to the liquid supply unit 1100 to supply a new liquid by replacing the liquid supply source 1100, and controls the additive supply unit 1200 to put the additive. However, the present invention is not limited thereto, and the controller 900 may determine only whether to put the rust inhibitor or to replace the liquid. In addition, the controller 900 may be provided to first put the additive without supplying the liquid after the liquid supply source 1100 is replaced.

According to the exemplary embodiment of the present invention, even when the liquid is acidified or ionized in an environment in which the liquid flows for a long time, corrosion of components may be prevented by recognizing the acidification or the ionization of the liquid in advance through the sensor unit 1400 and replacing the liquid or putting the additive. Accordingly, it is possible to improve the life and reliability of the apparatus.

In the above example, the present invention has been described based on the case where the liquid circulation unit 1000 is coupled to the liquid treating chamber 380 as an example. However, the present invention is not limited thereto, and the liquid circulation unit 1000 may be provided independently or may be provided in combination with other components in the substrate processing apparatus 10.

In addition, in the above-described example, the present invention has been described based on the case where the liquid is pure water as an example. However, the present invention is not limited thereto, and the liquid may be another type of liquid having an excellent heat transfer rate. When a liquid other than pure water is provided, the put additive may be determined according to the type of the liquid.

In addition, in the above-described example, the present invention has been described based on the case where the treatment liquid is a developer as an example. However, the present invention is not limited thereto, and the treatment liquid may be various types of treatment liquids used to process the substrate.

Also, in the above-described example, the present invention has been described based on the case where the liquid is provided to be circulated along the circulation line 1300 as an example. However, the present invention is not limited thereto, and may be provided as a supply line for supplying a liquid instead of the circulation line 1300.

In addition, in the above-described example, the present invention has been described based on the case where the circulation line 1500 is installed on the treatment liquid supply line 387c as an example. However, the present invention is not limited thereto, and the circulation line 1500 may be provided to be installed in other configurations requiring temperature maintenance.

In addition, in the above-described example, the present invention has been described based on the case where the sensor unit 1400 is a TDS sensor as an example. However, the present invention is not limited thereto, and the sensor unit 1400 may further include a pH sensor. The pH sensor may measure the pH of the liquid. The sensor unit 1400 may be provided to transmit the measured pH value to the controller 900. The controller 900 may determine whether to discharge and replace the liquid, and whether to put the additive, based on a pH value measured by a pH sensor.

In addition, in the above-described example, the present invention has been described based on the case where the circulation line 1400 joins the treatment liquid supply line 387c as an example. However, the present invention is not limited thereto, and the circulation line 1400 may be provided to return a liquid to the liquid supply source 1110.

It should be understood that exemplary embodiments are disclosed herein and that other variations may be possible. Individual elements or features of a particular exemplary embodiment are not generally limited to the particular exemplary embodiment, but are interchangeable and may be used in selected exemplary embodiments, where applicable, even when not specifically illustrated or described. The modifications are not to be considered as departing from the spirit and scope of the present invention, and all such modifications that would be obvious to one of ordinary skill in the art are intended to be included within the scope of the accompanying claims.

What is claimed is:

1. An apparatus for processing a substrate, the apparatus comprising:
a chamber for providing a treatment space for processing a substrate;
a treatment liquid supply unit for supplying a treatment liquid to the treatment space; and
a controller,
wherein the treatment liquid supply unit includes:
a treatment liquid supply source for storing the treatment liquid;
a nozzle for discharging the treatment liquid to the substrate;
a treatment liquid supply line for connecting the treatment liquid supply source and the nozzle; and
a liquid circulation unit that is provided to circulate a liquid adjacent to the liquid supply line to maintain a constant temperature of the liquid,
the liquid supply unit includes:
a liquid supply unit for storing and supplying the liquid;
a manifold to which the liquid is supplied from the liquid supply unit;
an additive supply unit for putting an additive to the manifold;
a circulation line provided to circulate a liquid supplied from the manifold to the liquid supply unit; and
a sensor unit for measuring a concentration of foreign substances in the liquid,
the circulation line is installed adjacent to the treatment liquid supply line, and
when a measurement value of the sensor unit is equal to or greater than a set value, the controller controls the liquid circulation unit to put the additive into the manifold.

2. The apparatus of claim 1, wherein the manifold includes a discharge line for discharging the liquid, and
the controller controls the liquid circulation unit to discharge the liquid through the discharge line when the measurement value of the sensor unit is equal to or greater than the set value.

3. The apparatus of claim 1, wherein the foreign substance is ion, and the additive lowers a concentration of the ions.

4. The apparatus of claim 3, wherein the foreign substance is ion, and the additive adsorbs the ion in the liquid.

5. The apparatus of claim 2, wherein the liquid supply unit includes:
a liquid supply source for storing the liquid; and
a liquid supply line for connecting the manifold and the liquid,
the liquid supply line, the circulation line, and the manifold are made of a material containing metal, and
the controller puts the additive to prevent ions from dissolving in the liquid supply line, the circulation line, and the manifold, from the circulation line.

6. The apparatus of claim 2, wherein the liquid supply unit includes:
a liquid supply source for storing the liquid; and
a liquid supply line for connecting the manifold and the liquid,
the controller puts the additive to form a film inside the liquid supply line, the manifold, and the circulation line.

7. The apparatus of claim 2, wherein the sensor unit is provided to measure pH of the liquid, and
the additive increases the pH of the liquid.

8. The apparatus of claim 2, wherein the treatment liquid is a developer.

9. The apparatus of claim 7, wherein the liquid is pure water.

10. The apparatus of claim 2, wherein the liquid supply unit includes:
a plurality of liquid supply sources for storing the liquid;
a plurality of liquid supply lines for connecting the plurality of liquid supply sources and the manifold; and
a valve installed in each of the plurality of liquid supply lines, and
when a measured concentration of the liquid supplied from any one of the plurality of liquid supply sources is equal to or greater than a set value, the controller controls the liquid circulation unit to discharge the liquid through the discharge line and supply the liquid from another liquid supply source among the plurality of liquid supply sources.

11. A unit for circulating a liquid, the unit comprising:
a liquid supply unit for storing and supplying a liquid;
a manifold to which the liquid is supplied from the liquid supply unit;
an additive supply unit for putting an additive to the manifold;
a circulation line provided to circulate the liquid supplied from the manifold to the liquid supply unit;
a sensor unit for measuring a concentration of foreign substances in the liquid; and
a controller,
wherein when a measurement value of the sensor unit is equal to or greater than a set value, the controller controls the additive supply unit to put the additive into the manifold.

12. The unit of claim 11, wherein the manifold includes a liquid discharge unit for discharging the liquid, and
when the measurement value of the sensor unit is equal to or greater than the set value, the controller controls the liquid discharge unit to discharge the liquid through the liquid discharge unit.

13. The unit of claim 12, wherein the liquid supply unit includes:
a liquid supply source for storing the liquid; and
a liquid supply line for connecting the manifold and the liquid,
the liquid supply line, the circulation line, and the manifold are made of a material containing metal, and
the controller puts the additive to prevent ions from dissolving in the liquid supply line, the circulation line, and the manifold, from the circulation line.

14. The unit of claim 13, wherein the liquid supply source is provided in plural,
the liquid supply line is provided to connect the plurality of liquid supply sources and the manifold,
the liquid supply line includes a valve corresponding to each of the liquid supply sources, and
when a measured concentration of the liquid supplied from any one of the plurality of liquid supply sources is equal to or greater than a set value, the controller controls the liquid circulation unit to discharge the liquid through the discharge line and supply the liquid from another liquid supply source among the plurality of liquid supply sources.

15. The unit of claim 13, wherein the controller puts the additive to form a film inside the liquid supply line, the manifold, and the circulation line.

16. The unit of claim 13, wherein the sensor unit is provided to measure pH of the liquid, and
the additive increases the pH of the liquid.

17. The unit of claim 13, wherein the liquid is pure water.

18. An apparatus for processing a substrate, the apparatus comprising:
a chamber for providing a treatment space for processing a substrate;
a treatment liquid supply unit for supplying a treatment liquid to the treatment space; and
a controller,
wherein the treatment liquid supply unit includes:
a treatment liquid supply source for storing the treatment liquid;
a nozzle for discharging the treatment liquid to the substrate;
a treatment liquid supply line for connecting the treatment liquid supply source and the nozzle; and
a liquid circulation unit that is provided to circulate the liquid adjacent to the treatment liquid supply line to maintain a constant temperature of the treatment liquid,
the liquid circulation unit includes:
a liquid supply unit for storing and supplying the liquid;
a manifold to which the liquid is supplied from the liquid supply unit;
an additive supply unit for putting an additive to the manifold;
a circulation line provided to circulate the liquid supplied from the manifold to the liquid supply unit;
a sensor unit for measuring a concentration of ions in the liquid; and
a liquid discharge unit for discharging the liquid, and
the circulation line is installed adjacent to the treatment liquid supply line, and
the liquid is pure water,
the additive is a rust inhibitor,
the liquid supply line, the circulation line, and the manifold are made of a material containing metal, and
when the concentration measured by the sensor unit is equal to or greater than a set value, the controller controls the liquid circulation unit to discharge the pure water to the discharge unit, supply the pure water into the manifold, and add the rust inhibitor.

19. The apparatus of claim 15, wherein the rust inhibitor is mixed with the pure water to reduce the concentration of the ions in the pure water.

20. The apparatus of claim 19, wherein the treatment liquid is a developer.
